(19) United States
(12) Patent Application Publication
(10) Pub. No.: US 2025/0191904 A1
(43) Pub. Date: Jun. 12, 2025

(54) APPARATUS AND METHOD OF TREATING SUBSTRATE

(71) Applicant: SEMES CO., LTD., Cheonan-si (KR)

(72) Inventors: So Young PARK, Cheonan-si (KR); Bok Kyu LEE, Cheonan-si (KR); Sung Bum PARK, Cheonan-si (KR)

(73) Assignee: SEMES CO., LTD., Cheonan-si (KR)

(21) Appl. No.: 18/968,854

(22) Filed: Dec. 4, 2024

(30) Foreign Application Priority Data
Dec. 6, 2023 (KR) 10-2023-0175277

(51) Int. Cl. H01L 21/02; H01L 21/67

(52) U.S. Cl. CPC H01L 21/02052; H01L 21/67051

(57) ABSTRACT

Disclosed are a substrate treating method and a substrate treating apparatus, and more specifically, a substrate treating apparatus that treats a substrate by controlling descending airflow supplied to a treatment space. The substrate treating method includes: a substrate treating operation of treating a substrate by supplying a treatment liquid from a treatment liquid supply nozzle to the substrate located in an interior space of a housing; and a negative pressure maintaining operation of maintaining the interior space at a negative pressure.

### CROSS-REFERENCE TO RELATED APPLICATIONS

This application claims priority to and the benefit of Korean Patent Application No. 10-2023-0175277 filed in the Korean Intellectual Property Office on Dec. 6, 2023, the entire contents of which are incorporated herein by reference.

### TECHNICAL FIELD

The present invention relates to a substrate treating method and a substrate treating apparatus, and more specifically, to a substrate treating apparatus that treats a substrate by adjusting a pressure of an interior space.

### BACKGROUND ART

A semiconductor process includes a process of cleaning a thin film, foreign substances, particles, and the like on a substrate. These processes are accomplished by placing a substrate on a spin head with a patterned side facing up or down, supplying a treatment liquid to the substrate while the spin head is rotated, and subsequently drying the wafer.

In the process of treating the substrate, harmful substances, such as fumes or toxic gas, that cause particles may occur. These harmful substances may be removed through a fan unit that supplies descending airflow to a chamber and an exhaust unit that exhausts the inside of the chamber. However, when the pressure inside the chamber is greater than or equal to the pressure outside the chamber, harmful substances may leak to the outside in the process of loading and unloading the substrate.

### SUMMARY OF THE INVENTION

The present invention has been made in an effort to provide a substrate treating apparatus and method capable of maintaining a pressure inside a chamber lower than a pressure outside the chamber during substrate treatment.

The present invention has also been made in an effort to provide a substrate treating apparatus and method capable of removing harmful substances, such as fumes or toxic gas, generated during substrate treatment.

The present invention has also been made in an effort to provide a substrate treating apparatus and method capable of preventing harmful substances, such as fumes or toxic gas, from leaking to the outside.

The problem to be solved by the present invention is not limited to the above-mentioned problems, and the problems not mentioned will be clearly understood by those skilled in the art from the descriptions below.

An exemplary embodiment of the present invention provides a method of treating a substrate, the method comprising: a substrate treating operation of treating a substrate by supplying a treatment liquid from a treatment liquid supply nozzle to the substrate located in an interior space of a housing; and a negative pressure maintaining operation of maintaining the interior space at a negative pressure.

According to the exemplary embodiment of the present invention, the negative pressure maintaining operation may be performed during the substrate treating operation.

According to the exemplary embodiment of the present invention, the method may further include after the substrate treating operation is completed, a negative pressure removing operation of forming a pressure of the interior space and a pressure of an exterior space that is the outside of the housing to be the same, wherein the shutter that opens and closes a substrate loading path of the housing may be opened after the negative pressure removing operation.

According to the exemplary embodiment of the present invention, in the negative pressure removing operation, the amount of descending airflow supplied to the interior space may be reduced than in the negative pressure maintaining operation.

According to the exemplary embodiment of the present invention, the method may further include an auto dispensing operation of regularly discharging a treatment liquid while the treatment liquid supply nozzle is waiting at a waiting port, without the substrate treating operation being performed, wherein the negative pressure maintaining operation may be performed during the auto dispensing operation.

According to the exemplary embodiment of the present invention, the method may further include a maintaining operation of opening the housing to maintain and repair an interior of the housing, wherein the negative pressure maintaining operation may be performed before the maintaining operation is performed.

According to the exemplary embodiment of the present invention, the method may further include an abnormality responding operation, wherein the abnormality responding operation includes, when a pressure of the interior space may be higher than a pressure of the exterior space during the substrate treating operation, reducing the amount of descending airflow supplied to the interior space or blocking the descending airflow.

According to the exemplary embodiment of the present invention, in the substrate treating operation, the treatment liquid may include a toxic liquid.

According to the exemplary embodiment of the present invention, the method may further include the abnormality responding operation may include blocking a path through which the descending airflow is introduced.

According to the exemplary embodiment of the present invention, in the substrate treating operation, the substrate may be treated with a treatment liquid including hydrochloric acid (HCl).

An exemplary embodiment of the present invention provides an apparatus for treating a substrate, the apparatus comprising: a housing having an interior space; a fan unit including a fan forming descending airflow into the interior space; a shutter for opening and closing a substrate entrance port, which is a passage through which a substrate is loaded into the interior space; a cup body, which is placed within the interior space and has a treatment space with an open top portion; a support unit for supporting a substrate within the treatment space; a liquid supply unit including a treatment liquid supply nozzle that supplies a treatment liquid to the substrate supported by the support unit; an exhaust unit for exhausting the treatment space or the interior space; and a controller for controlling the fan unit, the shutter, and the exhaust unit, wherein the controller controls the support unit, the liquid supply unit, and the exhaust unit to perform a substrate treating operation in which the substrate is treated by supplying the treatment liquid from the treatment liquid supply nozzle to the substrate located in the treatment space, and controls the fan unit to perform a negative pressure maintaining operation in which the interior space may be maintained at a negative pressure during the substrate treating operation.

According to the exemplary embodiment of the present invention, the controller controls the fan unit to further perform a negative pressure removing operation in which a pressure of the interior space and a pressure of the exterior space, which is the outside of the housing, are formed to be the same after the substrate treating operation is completed, and controls the shutter to be opened after the negative pressure removing operation.

According to the exemplary embodiment of the present invention, the method may further include a waiting port where the treatment liquid supply nozzle waits, wherein the controller controls the liquid supply unit and the waiting port to perform an auto dispensing operation in which a treatment liquid is regularly discharged while the treatment liquid supply nozzle is waiting at a waiting port, without the substrate treating operation being performed, and controls the fan unit to perform a negative pressure maintaining operation in which the interior space is maintain at a negative pressure during the auto dispensing operation.

According to the exemplary embodiment of the present invention, the method may further include a negative pressure sensor for measuring a difference between a pressure of the interior space and a pressure of the exterior space, wherein the fan unit further includes: a frame having an outside air introduction space; and an opening and closing mechanism for opening and closing a passage through which outside air is introduced into the outside air introduction space, and when the negative pressure sensor detects that the pressure in the interior space is higher than the pressure in the exterior space while treating the substrate, the controller controls the opening and closing mechanism to perform an abnormality responding operation in which the amount of the descending airflow may be reduced or the descending airflow is blocked.

According to the exemplary embodiment of the present invention, the method may further include the controller controls the fan unit to perform a negative pressure maintaining operation in which the interior space may be maintained at a negative pressure before performing a maintaining operation in which the housing is opened to maintain and repair the interior of the housing.

According to the exemplary embodiment of the present invention, the treatment liquid may be include a toxic liquid.

An exemplary embodiment of the present invention provides a method of treating a substrate, the method comprising: a substrate treating operation of treating a substrate by supplying a treatment liquid including a toxic liquid to a substrate located in an interior space of a housing; a negative pressure maintaining operation of maintaining the interior space at a negative pressure; and a negative pressure removing operation of forming a pressure of the interior space and a pressure of an exterior space, which is the outside of the housing, to be the same, wherein the negative pressure maintaining operation may be performed simultaneously with the substrate treating operation.

According to the exemplary embodiment of the present invention, an auto dispensing operation of discharging the treatment liquid from a treatment liquid supply nozzle while the treatment liquid supply nozzle supplying the treatment liquid is waiting at a waiting port, wherein the negative pressure maintaining operation may be simultaneously performed with the auto dispensing operation.

According to the exemplary embodiment of the present invention, the method may further include a maintaining operation of opening the housing to maintain the interior of the housing, wherein the negative pressure maintaining operation may be performed before the maintaining operation.

According to the exemplary embodiment of the present invention, the method may further include an abnormality responding operation of forming the pressure of the interior space to be lower than the pressure of the exterior space when a difference between the pressure of the interior space and the pressure of the exterior space is greater than 0 during the substrate treating operation, wherein the abnormality responding operation includes forming the pressure of the interior space to be low by blocking a path of airflow toward the interior space.

According to the exemplary embodiment of the present invention, it is possible to maintain the pressure inside the chamber to be lower than the pressure outside the chamber during substrate treatment.

Further, according to the exemplary embodiment of the present invention, it is possible to remove harmful substances, such as fumes or toxic gas, generated during substrate treatment.

Further, according to the exemplary embodiment of the present invention, it is possible to prevent harmful substances, such as fumes or toxic gas, from leaking to the outside.

The effect of the present invention is not limited to the foregoing effects, and those skilled in the art may clearly understand non-mentioned effects from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view schematically illustrating a substrate treating apparatus according to an exemplary embodiment of the present invention.

FIG. 2 is a diagram schematically illustrating an exemplary embodiment of a liquid treating chamber of FIG. 1.

FIG. 3 is a flowchart illustrating a substrate treating method according to the present invention.

FIG. 4 is a flowchart illustrating a substrate treating operation of FIG. 3.

FIG. 5 is a graph illustrating a change in a pressure difference between a pressure of an interior space and a pressure of an exterior space according to implementation of the substrate treating method of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

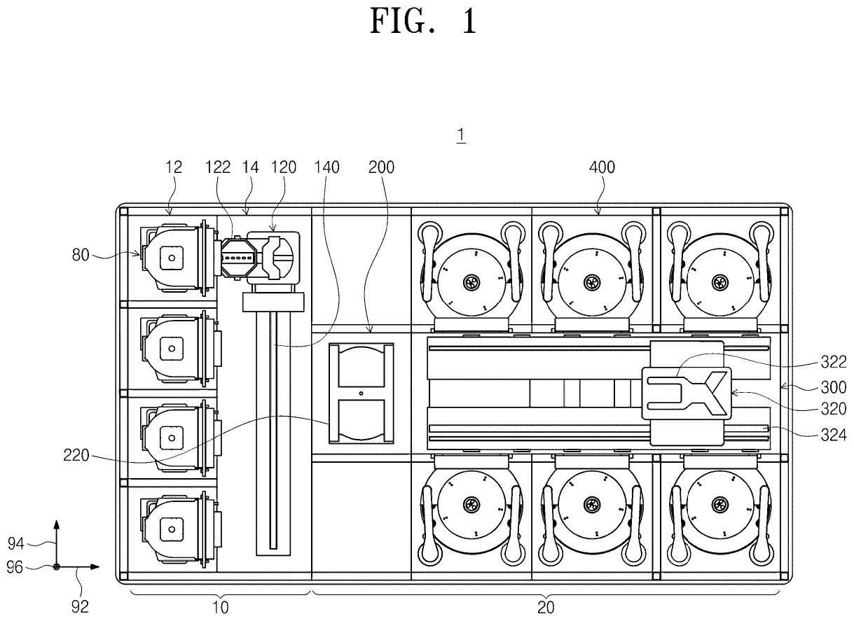

FIG. 1 is a top plan view schematically illustrating a substrate treating apparatus according to an exemplary embodiment of the present invention.

Referring to FIG. 1, a substrate treating apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the vertical direction, and the hands 122 may move forwardly and backwardly independently of each other.

The treating module 20 includes a buffer unit 200, a transfer chamber 300, and a treating chamber 400. The buffer unit 200 provides a space in which the substrate W loaded into the treating module 20 and the substrate W unloaded from the treating module 20 stay temporarily. The treating chamber 400 performs a treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on both sides of the transfer chamber 300. At each of both sides of the transfer device 300, the liquid treating devices 400 may be provided in an array of A×B (each of A and B is 1 or a natural number larger than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

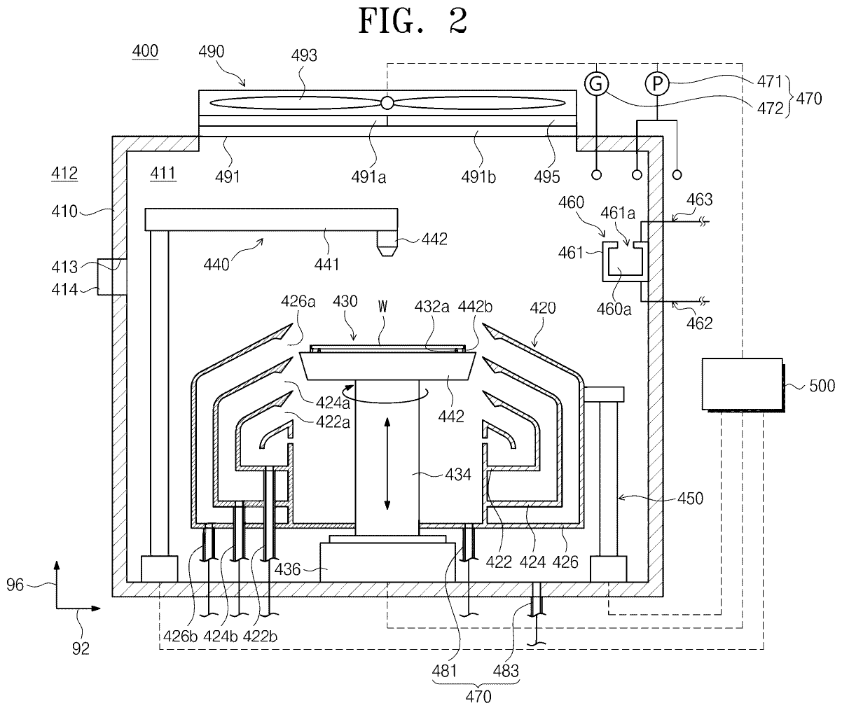

FIG. 2 is a diagram schematically illustrating an exemplary embodiment of the liquid treating chamber of FIG. 1. Referring to FIG. 2, the liquid treating chamber 400 includes a housing 410, a cup 420, a support unit 430, a nozzle unit 440, a lifting unit 450, a waiting port 460, a sensor unit 470, an exhaust unit 480, a fan unit 490, and a controller.

The housing 410 is provided in a generally rectangular parallelepiped shape. The housing 410 provides an interior space 411. An outer side of the housing 410 is defined as an exterior space 412. The exterior space 412 may be a transfer space in which the transfer robot 320 is located in the transfer chamber 300. The cup 420, the support unit 430, the nozzle unit 440, the lifting unit 450, the waiting port 460, a negative pressure sensor 470, a gas sensor 480, and the fan unit 490 are disposed in the interior space 411. An entrance port 413 through which the substrate W enters and exits is formed on the lateral wall of the housing 410. The entrance port 413 may be maintained in an open state. A shutter 414 may be provided in the entrance 413 to open and close the entrance port 413.

The cup 420 has a treatment space 421 having an open top, and the substrate W is liquid-treated in the treatment space 421. The treatment space 421 may be included in the interior space 411. Also, the treatment space 421 may be a part of the interior space 411. The support unit 430 supports the substrate W within the treatment space 421. The lifting unit 450 adjusts a relative height between the cup 420 and the support unit 430.

According to the example, the cup 420 includes a plurality of recovery containers 422, 424, and 426. Each of the recovery containers 422, 424, and 426 has a recovery space of recovering the liquid used for the treatment of the substrate. Each of the recovery containers 422, 424, and 426 is provided in a ring shape surrounding the support unit 430. When the liquid treatment process is in progress, the treatment liquid scattered by the rotation of the substrate Wis introduced into the recovery space through inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 430, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 2640 has a support plate 2642 and a drive shaft 430. An upper surface of the support plate 432 may be provided in a generally circular shape, and may have a diameter larger than a diameter of the substrate W. In the center portion of the support plate 432, a support pin 432a is provided to support the rear surface of the substrate W, and the support pin 432a is provided with its upper end protruding from the support plate 432 so that the substrate W is spaced apart from the support plate 432 by a certain distance. A chuck pin 432b is provided to an edge of the support plate 432. The chuck pin 432b is provided to protrude upwardly from the support plate 432, and supports the lateral portion of the substrate W so that the substrate W is not separated from the support unit 430 when the substrate W is rotated. A drive shaft 434 is driven by a driver 436, is connected to the center of the bottom surface of the substrate W, and rotates the support plate 432 with respect to the central axis thereof.

The nozzle unit 440 includes an arm 441 and a treatment liquid nozzle 442. The arm 441 supports the treatment liquid nozzle 442. The arm 441 moves the treatment liquid nozzle 442. The treatment liquid nozzle 442 supplies the treatment liquid onto the substrate W. According to the embodiment, the treatment liquid may be a solution including a toxic liquid. Also, the treatment liquid may be a solution including hydrochloric acid (HCl) as a toxic liquid.

Optionally, the nozzle unit 440 may further include one or more nozzles in addition to the treatment liquid nozzle 442. Additional nozzles may supply different types of treatment liquids to the substrate. For example, the other type of treatment liquid may be an acid solution or a base solution for removing foreign substances on the substrate. In addition, another type of treatment liquid may be alcohol having surface tension lower than that of water. For example, the alcohol may be isopropyl alcohol. In addition, the added nozzles are supported by the different arms 441 from the treatment liquid nozzle 442, respectively, and these arms 441 may be moved independently. Optionally, the treatment liquid nozzle 442 and the nozzle added may be mounted on the same arm and moved simultaneously.

The lifting unit 450 moves the cup 420 in the up and down direction. By the up and down movement of the cup 420, a relative height between the cup 420 and the substrate W is changed. Accordingly, the recovery containers 422, 424, and 426 for recovering the treatment liquid are changed according to the type of liquid supplied to the substrate W, and thus the liquids may be separated and recovered. Unlike the description, the cup 420 may be fixedly installed, and the lifting unit 450 may move the support unit 430 in the vertical direction.

The treatment liquid nozzle 442 stands by at the waiting port 460. The waiting port 460 includes a body 461, a discharge unit 462, and an exhaust unit 463. The body 461 provides a waiting space 460a in which the treatment liquid nozzle 442 stands by. The body 461 may have a shape in which an upper portion is opened. Alternatively, an opening 461a in which the treatment liquid nozzle 442 is located may be formed in an upper portion of the body 461. While waiting, the treatment liquid nozzle 442 may discharge the treatment liquid into the waiting space 460a. According to the embodiment, the treatment liquid nozzle 442 may discharge the treatment liquid every predetermined time so that the treatment liquid may be prevented from solidifying in the treatment liquid nozzle 442. Furthermore, before treating the substrate W with the treatment liquid, the treatment liquid may be discharged stably onto the substrate W. The discharge unit 462 discharges the discharged treatment liquid to the outside of the waiting port 460. The discharge unit 462 may include a discharge pipe (not illustrated), a valve (not illustrated), and a pump (not illustrated). The exhaust unit 463 may exhaust the waiting space 460a. The exhaust unit 463 may remove fumes or toxic gas generated from the treatment liquid discharged into the waiting space 460a. The exhaust unit 463 may include an exhaust pipe (not illustrated), a valve (not illustrated), and a pump (not illustrated).

The sensor unit 470 includes a negative pressure sensor 471 and a gas sensor 472. The negative pressure sensor 471 detects whether the pressure of the interior space 411 of the housing 410 is lower than the pressure of the exterior space 412. Hereinafter, the negative pressure refers to a state in which the pressure of the interior space 411 is lower than the pressure of the exterior space 412. The controller 500 may control the rotation speed of the fan 493 according to whether the negative pressure sensor 471 detects the negative pressure. The gas sensor 472 detects the generation of fumes or toxic gas in the interior space 411 of the housing 410. The gas sensor 472 may be installed in the interior space 411. The controller may control the rotation speed of the fan 493 according to whether the gas sensor 472 detects whether gas is generated.

The exhaust unit 480 exhausts the interior space 411. The exhaust unit 480 may be connected to an exhaust duct (not illustrated) or the like. The exhaust unit 480 may exhaust the interior space 411 with a constant exhaust amount. The exhaust unit 480 includes a cup exhaust unit 481 and an environmental exhaust unit 483.

The cup exhaust unit 481 exhausts the treatment space 421. The cup exhaust unit 481 exhausts gas generated in a process of liquid-treating the substrate W. Furthermore, the cup exhaust unit 481 exhausts gas generated from a treatment liquid recovered in the recovery cups 422, 424, and 426. The cup exhaust unit 481 may be installed in a region of the lower wall of the cup 420 that does not overlap the recovery pipes 422b, 424b, and 426b. Furthermore, the cup exhaust unit 481 may be installed in a central region of the lower wall of the cup 420 that does not overlap the drive shaft 434 and the driver 436.

The environmental exhaust unit 483 may be installed in the lower wall of the housing 410. The environmental exhaust unit 483 exhausts the interior space 411 of the housing 410. Also, the environmental exhaust unit 483 may exhaust gas that has not been exhausted by the cup exhaust unit 481.

The fan unit 490 may be installed on the upper wall of the housing 410. The fan unit 490 introduces outside air into the interior space 411. The fan unit 490 forms descending airflow in the interior space 411 of the housing 410. The fan unit 490 includes a frame 491, a fan 493, and an opening/closing mechanism 495. The frame 491 is located in a central region in the upper wall of the housing 410. The fan 493 is installed on the upper portion of the frame 491. The frame 491 provides a passage 491a through which outside air is introduced into the lower portion of the fan 493. Also, the frame 491 provides an outside air introduction space 491b in a lower portion of the passage 491a. The 493 rotates to introduce outside air into the interior space 411. The outside air is introduced into the interior space 411 through the fan 493, the passage 491a, and the outside air introduction space 491b. The pressure of the interior space 411 may be adjusted by controlling the rotation speed of the fan 491. Accordingly, negative pressure may be formed in the interior space 411. The opening/closing mechanism 495 may be installed in the passage 491a. The opening/closing mechanism 495 opens/closes the passage 491a. The opening/closing mechanism 495 may be provided as a shutter. However, the present invention is not limited thereto, and any form may be sufficient as long as the passage 491a may be blocked. The opening/closing mechanism 495 may control the descending airflow by opening/closing the passage 491a. The opening/closing mechanism 495 may quickly block the descending airflow by closing the passage 491a. According to the example, the opening/closing mechanism 495 may block the passage during an abnormality responding operation S310 to be described later, thereby lowering the pressure of the interior space 411.

The controller 500 may treat the substrate W by controlling the substrate treating apparatus according to the embodiment of the present invention. Hereinafter, a method of treating a substrate by using the substrate treating apparatus according to the embodiment of the present invention by the controller will be described.

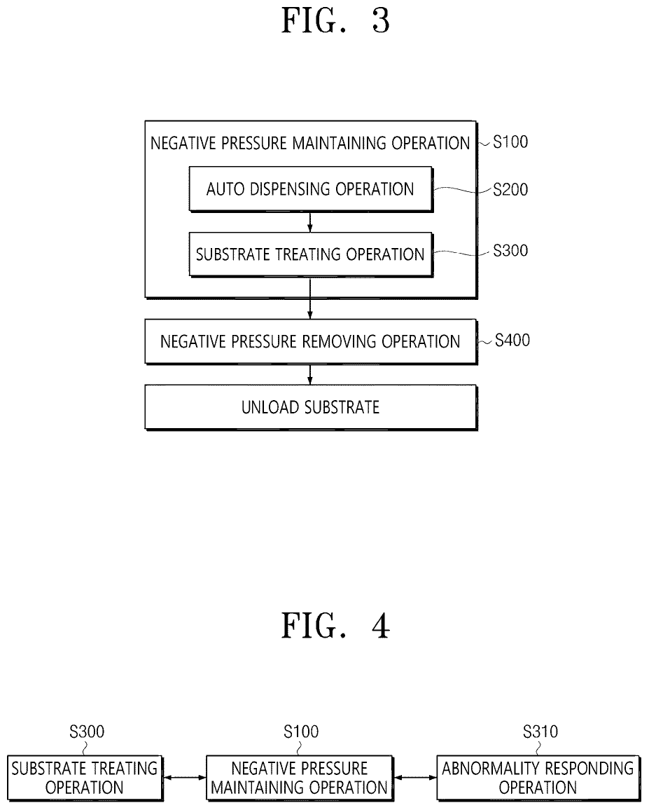

FIG. 3 is a flowchart illustrating a substrate treating method according to the present invention. Referring to FIG. 3, a substrate treating method includes a negative pressure maintaining operation S100, an auto dispensing operation S200, a substrate treating operation S300, and a negative pressure removing operation S400.

The negative pressure maintaining operation S100 is an operation of forming and maintaining the pressure of the interior space 411 to be lower than the pressure of the exterior space 412. During the negative pressure maintaining operation, the rotation speed of the fan 493 may be lowered to reduce the pressure of the interior space 411. According to the example, the pressure of the interior space 411 may be formed to be 10 Pa lower than the pressure of the exterior space 412.

The negative pressure maintaining operation S100 may be performed simultaneously with the auto dispensing operation S200 and the substrate treating operation S300 to be described later. During the negative pressure maintaining operation S100, the interior space 411 may be replaced with the outside air introduced by the fan 493. Accordingly, fumes and the like generated during the auto dispensing operation S200 and the substrate treating operation S300 may be prevented from being leaked to the outside.

The auto dispensing operation S200 is an operation of not treating the substrate W in the liquid treating chamber 400. The auto dispensing operation S200 is an operation of spraying the treatment liquid every predetermined time from the treatment liquid nozzle 442 waiting in the waiting port 460 without the substrate W being loaded into the treatment space 412. Coagulation of the treatment liquid in the treatment liquid nozzle 442 may be prevented by spraying the treatment liquid at predetermined time intervals. The auto dispensing operation S200 may be performed a plurality of times as the waiting time increases.

FIG. 4 is a flowchart illustrating the substrate treating operation of FIG. 3. The substrate treating operation S300 is an operation of treating the substrate by supplying the treatment liquid onto the substrate W located in the support unit 430. The treatment liquid is discharged onto the substrate W from the treatment liquid nozzle 442. The substrate W may be rotated by the support unit 430 while the treatment liquid is being discharged or after the treatment liquid is discharged. Thus, the treatment liquid may be applied onto the substrate W. The applied treatment liquid may react with the substrate W or a film formed on the substrate W. During the substrate treating operation S300, the negative pressure maintaining operation S100 may be simultaneously performed. Thus, while the substrate W is treated with the treatment liquid, the pressure of the interior space 411 may be maintained to be lower than the pressure of the exterior space 412.

The substrate treating operation S300 may include an abnormality responding operation S310. In the abnormality responding operation S310, when a pressure difference between the interior space 411 and the exterior space 412 is greater than or equal to 0 while the substrate W is treated, the abnormality responding operation S310 may be performed. In the abnormality responding operation S310, the amount of descending airflow supplied to the interior space 411 may be reduced or blocked. In one example, a problem may occur in the exhaust duct connected to the exhaust unit 480 or the facilities or equipment that manage the same, and thus the pressure in the interior space 411 may not be properly controlled. During the abnormality responding operation S310, the opening/closing mechanism 495 may block the path of airflow toward the interior space 411. During the abnormality responding operation S310, the opening/closing mechanism 495 may close the upper portion of the fan unit 490. Accordingly, the pressure in the interior space 411 may be quickly reduced.

The negative pressure removing operation S400 may be performed after the negative pressure maintaining operation S100. The negative pressure removing operation S400 is an operation of forming the pressure of the interior space 411 and the pressure of the exterior space 412 to be the same. According to the example, the negative pressure may be removed by increasing the rotation speed of the fan 493 to increase the pressure of the interior space 411. When the pressure of the interior space becomes the same as the pressure of the exterior space, the shutter 414 may be opened to take out the substrate W. Also, when the negative pressure maintaining operation S100 is performed simultaneously with the automatic dispensing operation S200, the negative pressure removing operation S400 may be performed to load in the substrate W after the auto dispensing operation S200.

A maintaining operation S500 is an operation of maintaining and repairing the liquid treating chamber 400. During the maintaining operation S500, the housing 410 may be opened. According to the example, a door (not illustrated) is installed in the housing 410, and the door is opened so that a worker may perform maintenance and repair work within the housing 410. The maintaining operation S500 may be performed before the negative pressure maintaining operation S100. Accordingly, even when the housing 410 is opened, fumes or gas generated in the interior space 411 may be prevented from being discharged to the outside.

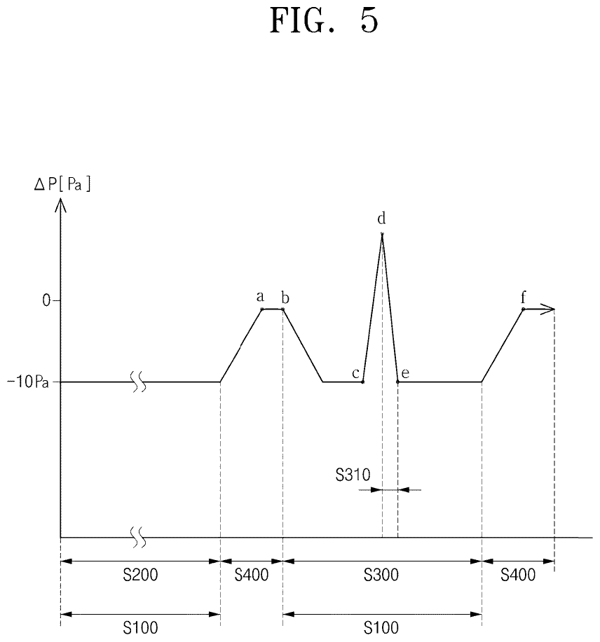

FIG. 5 is a graph illustrating a pressure difference (ΔP=P1−P2) between a pressure P1 of the interior space and a pressure P2 of the exterior space according to implementation of the substrate treating method of the present invention. Referring to FIG. 5, while the negative pressure maintaining operation S100 is performed during the auto dispensing operation S200 in which the substrate W is not treated, the interior space 411 may be provided with a negative pressure, for example, −10 Pa. Accordingly, it is possible to prevent fumes or the like generated during the auto dispensing operation S200 from leaking to the outside. Also, the auto dispensing operation S200 may be repeated a plurality of times before the substrate W is treated.

After the auto dispensing operation S200, the negative pressure removing operation S400 is performed to load the substrate W into the treatment space 412. Accordingly, the pressure difference ΔP may become 0. When the pressure difference ΔP becomes 0, the shutter 414 is opened from a time point a, and the substrate W is loaded into the treatment space 412. Thereafter, at a time point b, the shutter 414 is closed, and the substrate treating operation S300 may be performed.

In the substrate treating operation S300, the substrate W is treated with a treatment liquid. The treatment liquid may be a liquid including a toxic substance. During the substrate treating operation S300, a pressure in the interior space 411 may be instantaneously increased due to a problem that occurs in an exhaust duct to which the substrate treating apparatus is connected or a facility managing the same according to the embodiment of the present invention. When the pressure rises at a time point c and the negative pressure disappears, the abnormality responding operation S310 may be performed. When the abnormality responding operation S310 is performed at a time point d, the descending airflow is controlled through the opening/closing mechanism 495. The opening/closing mechanism 495 closes the passage 491a. Accordingly, the opening/closing mechanism 495 may block the descending airflow supplied to the interior space 411. Closing the opening/closing mechanism 495 may quickly reduce the pressure of the interior space 411 than lowering the speed of the fan 493. Accordingly, the negative pressure may be re-formed in the interior space 411. When the abnormality responding operation S310 is terminated, the negative pressure maintaining operation S100 is performed again and the negative pressure is maintained.

After the substrate treating operation S400, the negative pressure removing operation S400 is performed to unload the substrate W. Accordingly, the pressure difference ΔP may become 0. When the pressure difference ΔP becomes 0, the shutter 414 is opened from a time point f, and the substrate W is unloaded from the treatment space 412.

According to the embodiment of the present invention, by performing the negative pressure maintaining operation S100 before opening the shutter 414, the pressure of the interior space 411 is formed to be lower than the pressure of the exterior space 412, leakage of harmful substances, such as fumes or toxic gas, into the exterior space 412 may be prevented.

In addition, by exhausting the harmful substances from the interior space 411 and replacing the atmosphere with outside air, it is possible to prevent leakage of harmful substances, such as fumes or toxic gas, into the exterior space 412.

In addition, even when the interior space 411 is not properly exhausted due to a problem with the exhaust facility connected to the liquid treating chamber 400 of the present invention, the pressure of the interior space 411 may be quickly lowered through the opening and closing mechanism 495 to form and maintain the pressure of the interior space as a negative pressure.

In the above-described example, it has been described as an example that the negative pressure sensor 470 is provided as the negative pressure sensing means. However, the present invention is not limited thereto, and pressure sensors are installed in the interior space 411 and the exterior space 412, respectively, and the controller may check whether negative pressure is generated based on the pressure value measured from each pressure sensor.

Furthermore, in the above-described example, the present invention has been described only based on the case where the substrate W is treated during the substrate treating operation S200 as an example. However, the present invention is not limited thereto, and the substrate treating operation S200 may further include a pre-dispensing operation. The pre-dispensing operation is an operation of spraying the treatment liquid from the waiting port 460 before discharging the treatment liquid from the treatment liquid nozzle 442 to the substrate W. The substrate W may be loaded into the treatment space 412 and supported by the support unit 430. The treatment liquid is not directly discharged to the substrate W but is first discharged from the waiting port 460 to stably discharge the treatment liquid, thereby preventing scattering of the treatment liquid when discharging the treatment liquid onto the substrate W.

In addition, in the above-described example, the present invention has been described only based on the case where the fan unit 490 is provided as an example. However, the present invention is not limited thereto, and the fan unit 490 may be provided as a fan filter unit in which a filter is provided, and may further include a plurality of fans 491.

Furthermore, in the above-described example, the present invention has been described only based on the case where the shutter 414 is opened when the pressure difference ΔP is 0 as an example. However, the present invention is not limited thereto, and the shutter 414 may be opened even when the pressure difference ΔP is a negative pressure of −2 Pa to −5 Pa.

In addition, in the above-described example, the present invention has been described only based on the case where the abnormality responding operation S310 is performed when the pressure difference ΔP is 0 or more as an example. However, the present invention is not limited thereto, and the abnormality responding operation S310 may be performed when there is a possibility that gas or the like may leak to the outside even though the pressure difference ΔP) is less than 0.

The foregoing detailed description illustrates the present invention. In addition, the above description shows and describes the exemplary embodiments of the present invention, and the present invention may be used in various other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. In addition, the appended claims should be construed to include other exemplary embodiments as well.

1. A method of treating a substrate, the method comprising:
a substrate treating operation of treating a substrate by supplying a treatment liquid from a treatment liquid supply nozzle to the substrate located in an interior space of a housing; and
a negative pressure maintaining operation of maintaining the interior space at a negative pressure.

2. The method of claim 1, wherein the negative pressure maintaining operation is performed during the substrate treating operation.

3. The method of claim 1, further comprising:
after the substrate treating operation is completed, a negative pressure removing operation of forming a pressure of the interior space and a pressure of an exterior space that is the outside of the housing to be the same,
wherein the shutter that opens and closes a substrate loading path of the housing is opened after the negative pressure removing operation.

4. The method of claim 3, wherein in the negative pressure removing operation, the amount of descending airflow supplied to the interior space is reduced than in the negative pressure maintaining operation.

5. The method of claim 1, further comprising:
an auto dispensing operation of regularly discharging a treatment liquid while the treatment liquid supply nozzle is waiting at a waiting port, without the substrate treating operation being performed,
wherein the negative pressure maintaining operation is performed during the auto dispensing operation.

6. The method of claim 1, further comprising:
a maintaining operation of opening the housing to maintain and repair an interior of the housing,
wherein the negative pressure maintaining operation is performed before the maintaining operation is performed.

7. The method of claim 1, further comprising:
an abnormality responding operation,
wherein the abnormality responding operation includes, when a pressure of the interior space is higher than a pressure of the exterior space during the substrate treating operation, reducing the amount of descending airflow supplied to the interior space or blocking the descending airflow.

8. The method of claim 7, wherein in the substrate treating operation, the treatment liquid includes a toxic liquid.

9. The method of claim 7, wherein the abnormality responding operation includes blocking a path through which the descending airflow is introduced.

10. The method of claim 8, wherein in the substrate treating operation, the substrate is treated with a treatment liquid including hydrochloric acid (HCl).

11.-16. (canceled)

17. A method of treating a substrate, the method comprising:
a substrate treating operation of treating a substrate by supplying a treatment liquid including a toxic liquid to a substrate located in an interior space of a housing;
a negative pressure maintaining operation of maintaining the interior space at a negative pressure; and
a negative pressure removing operation of forming a pressure of the interior space and a pressure of an exterior space, which is the outside of the housing, to be the same,
wherein the negative pressure maintaining operation is performed simultaneously with the substrate treating operation.

18. The method of claim 17, further comprising:
an auto dispensing operation of discharging the treatment liquid from a treatment liquid supply nozzle while the treatment liquid supply nozzle supplying the treatment liquid is waiting at a waiting port,
wherein the negative pressure maintaining operation is simultaneously performed with the auto dispensing operation.

19. The method of claim 17, further comprising:
a maintaining operation of opening the housing to maintain the interior of the housing,
wherein the negative pressure maintaining operation is performed before the maintaining operation.

20. The method of claim 17, further comprising:
an abnormality responding operation of forming the pressure of the interior space to be lower than the pressure of the exterior space when a difference between the pressure of the interior space and the pressure of the exterior space is greater than 0 during the substrate treating operation,
wherein the abnormality responding operation includes forming the pressure of the interior space to be low by blocking a path of airflow toward the interior space.
